(19) United States
(12) Patent Application Publication
(10) Pub. No.: US 2024/0005075 A1
(43) Pub. Date: Jan. 4, 2024

(54) GRAPHIC NEURAL NETWORK ACCELERATION SOLUTION WITH CUSTOMIZED BOARD FOR SOLID-STATE DRIVES

(71) Applicant: Alibaba (China) Co., Ltd., Hangzhou (CN)

(72) Inventors: Shuangchen LI, Sunnyvale, CA (US); Dimin NIU, Sunnyvale, CA (US); Hongzhong ZHENG, Los Gatos, CA (US)

(21) Appl. No.: 18/071,970

(22) Filed: Nov. 30, 2022

(30) Foreign Application Priority Data
Jul. 1, 2022 (CN) 202210773929.2

(51) Int. Cl. G06F 30/34; G06F 30/331

(52) U.S. Cl. CPC G06F 30/34; G06F 30/331

(57) ABSTRACT

This application describes systems and methods for facilitating memory access for graph neural network (GNN) processing. An example method includes fetching, by an access engine circuitry implemented on a circuitry board, a portion of structure data of a graph from one or more of a plurality of flash memory drives implemented on the circuitry board; performing node sampling using the fetched portion of the structure data of the graph to select one or more sampled nodes; fetching a portion of attribute data of the graph from two or more of the plurality of memory drives in parallel according to the selected one or more sampled nodes; sending the fetched portion of the attribute data of the graph to a host outside of the circuitry board; and performing, by the host, GNN processing for the graph using the fetched portion of the attribute data of the graph.

### CROSS-REFERENCE TO RELATED APPLICATION

This application claims priority to and benefits of Chinese patent Application No. 202210773929.2, filed with the China National Intellectual Property Administration (CNIPA) on Jul. 1, 2022. The entire contents of the above-identified application are incorporated herein by reference.

### TECHNICAL FIELD

The disclosure relates generally to customized board for memory accessing.

### BACKGROUND

While traditional deep learning models are good at pattern recognition and data mining by capturing hidden patterns of Euclidean data (e.g., images, text, videos), graph neural networks (GNNs) have shown to extend the power of machine learning to non-Euclidean domains represented as graphs with complex relationships and interdependencies between objects. Research has shown that GNNs can exceed state-of-the-art performance on applications ranging from molecular inference to community detection.

GNNs can be a very effective model for unstructured data modeling and processing. Recently, GNNs are becoming more and more utilized in applications such as recommendation systems, risk control systems, etc. Graph data may be unstructured. As a result, accessing graph data may result in random memory accesses.

### SUMMARY

Various embodiments of the present specification may include hardware circuits, systems, methods for efficient memory allocation for sparse matrix multiplications.

According to one aspect, a system comprises a host, and a circuitry board, wherein the circuitry board comprises: a plurality of memory drives configured to store structure data of a graph and attribute data of the graph; and an access engine circuitry communicatively coupled with each of the plurality of memory drives and the host, wherein the access engine circuitry is configured to: fetch a portion of the structure data of the graph from one or more of the plurality of memory drives; perform node sampling using the fetched portion of the structure data to select one or more sampled nodes; fetch a portion of the attribute data of the graph from two or more of the plurality of memory drives in parallel according to the selected one or more sampled nodes; and send the fetched portion of the attribute data of the graph to the host; and the host is communicatively coupled with the circuitry board and configured to receive the portion of the attribute data of the graph from the circuitry board, the host comprising: one or more processors configured to perform graph neural network (GNN) processing for the graph using the portion of the attribute data of the graph.

In some embodiments, the access engine circuitry is implemented on a field programmable gate array (FPGA) located on the circuitry board.

In some embodiments, in the system, the plurality of memory drives on the circuitry board are solid state drives (SSDs).

In some embodiments, the plurality of memory drives on the circuitry board have the same memory capacity.

In some embodiments, the access engine circuitry is further configured to access the structure data and the attribute data of the graph from a memory location outside of the circuitry board.

In some embodiments, the one or more processors of the host are central processing units (CPUs), graphics processing units (GPUs), tensor processing units (TPU), neural processing units (NPUs), or graph neural network processing units.

In some embodiments, the host further comprises: one or more double data rate (DDR) synchronous dynamic random access memory (SDRAM) communicatively coupled with the one or more processors of the host and the circuitry board, the one or more DDR SDRAM configured to: store the portion of the attribute data of the graph from the circuitry board; and facilitate the one or more processors of the host to perform GNN processing.

In some embodiments, the circuitry board further comprises a dedicated memory communicatively coupled to the access engine circuitry, wherein the dedicated memory is one or more double data rate (DDR) synchronous dynamic random access memory (SDRAM) and is configured to facilitate an implementation of one or more controllers for controlling access to the plurality of memory drives.

In some embodiments, the host is communicatively coupled with a plurality of the circuitry boards, and the host is configured to communicate with each of the plurality of the circuitry boards in parallel.

In some embodiments, the host is further configured to perform memory management on the plurality of the circuitry boards using open-channel controllers of a plurality of access engine circuitries in the plurality of the circuitry boards.

According to another aspect, a computer-implemented method comprises: fetching, by an access engine circuitry implemented on a circuitry board, a portion of structure data of a graph from one or more of a plurality of memory drives implemented on the circuitry board; performing, by the access engine circuitry, node sampling using the fetched portion of the structure data of the graph to select one or more sampled nodes; fetching, by the access engine circuitry, a portion of attribute data of the graph from two or more of the plurality of memory drives in parallel according to the selected one or more sampled nodes; sending, by the access engine circuitry, the fetched portion of the attribute data of the graph to a host, wherein the host is outside of the circuitry board; and performing, by one or more processors of the host, graph neural network (GNN) processing for the graph using the fetched portion of the attribute data of the graph.

According to another aspect, a non-transitory computer-readable storage medium stores instructions that, when executed by one or more processors, cause the one or more processors to perform operations comprising: fetching, by an access engine circuitry implemented on a circuitry board, a portion of structure data of a graph from one or more of a plurality of memory drives implemented on the circuitry board; performing, by the access engine circuitry, node sampling using the fetched portion of the structure data of the graph to select one or more sampled nodes; fetching, by the access engine circuitry, a portion of attribute data of the graph from two or more of the plurality of memory drives in parallel according to the selected one or more sampled nodes; and sending, by the access engine circuitry, the fetched portion of the attribute data of the graph to a host to make the host perform graph neural network (GNN) processing for the graph using the fetched portion of the attribute data of the graph, wherein the host is outside of the circuitry board.

These and other features of the systems, methods, and hardware devices disclosed, and the methods of operation and functions of the related elements of structure and the combination of parts and economies of manufacture will become more apparent upon consideration of the following description and the appended claims referring to the drawings, which form a part of this specification, where like reference numerals designate corresponding parts in the figures. It is to be understood, however, that the drawings are for illustration and description only and are not intended as a definition of the limits of the invention.

### BRIEF DESCRIPTION OF THE DRAWINGS

FIG. 1 is a schematic of an example graph, according to some embodiments of this specification.

FIG. 2 is a schematic of an example system using GNN accelerator architecture, according to some embodiments of this specification.

FIG. 3 is a schematic of an example system for accelerating GNN performance, according to some embodiments of this specification.

FIG. 4 is a schematic of an example GNN access engine, according to some embodiments of this specification.

FIG. 5 is a schematic of an example system for accessing GNN data from one or more memories on a circuitry board, according to some embodiments of this specification.

FIG. 6 is a schematic of an example circuitry board for accessing GNN data from a plurality of memories on a circuitry board, according to some embodiments of this specification.

FIG. 7 is a schematic of an example system for accessing GNN data from a plurality of circuitry boards, according to some embodiments of this specification.

FIG. 8 is an example method for accelerating GNN processing with one or more memories on a circuitry board, according to some embodiments of this specification.

### DETAILED DESCRIPTION

The specification is presented to enable any person skilled in the art to make and use the embodiments, and is provided in the context of a particular application and its requirements. Various modifications to the disclosed embodiments will be readily apparent to those skilled in the art, and the general principles defined herein may be applied to other embodiments and applications without departing from the spirit and scope of the present specification. Thus, the specification is not limited to the embodiments shown but is to be accorded the widest scope consistent with the principles and features disclosed herein.

Data may be structured or unstructured. For structured data, information may be arranged according to a pre-set data model or schema. For unstructured data, information may not be arranged using a preset-data model or a pre-defined manner. For example, a text file (e.g., emails, reports, etc.) may include information (e.g., individual letters or words) that does not have a pre-defined structure. As a result, the unstructured data may include irregularities and ambiguities that make it difficult to understand using traditional programs or data structures. Moreover, accessing unstructured data from a computer memory can involve a large number of random memory accessing, which can make memory accessing tedious and inefficient.

One way to represent unstructured data is by using graphs. A graph is a data structure comprising two components—nodes (or vertices) and edges. For example, a graph G may be defined as a collection of a set of nodes V and a set of edges E connecting the set of nodes. A node in a graph may have a set of features or attributes (e.g., a user profile in a graph representing a social network). A node may be defined as an adjacent node of another node, if they are connected by an edge. The graph may be a highly flexible data structure, as the graph may not require pre-defined rules to determine how many nodes it contains or how the nodes are connected by edges. Because the graph may provide great flexibility, it is one of the data structures that are widely used to store or represent unstructured data (e.g., text files). For example, the graph can store data that has a relationship structure, such as between buyers or products in an online shopping platform.

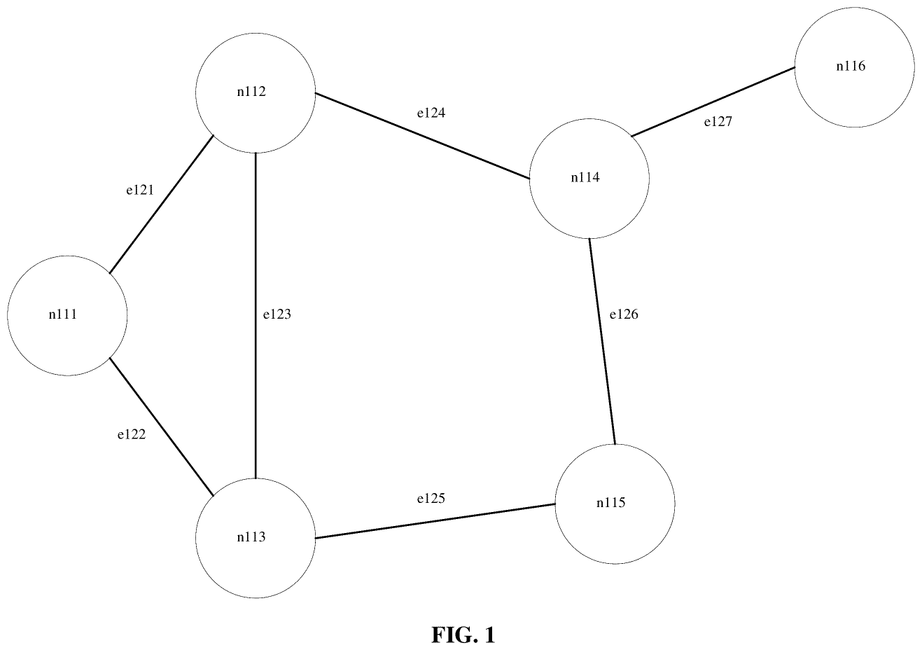

FIG. 1 is a schematic of an example graph, according to some embodiments of this specification. As shown in FIG. 1, a graph 100 comprises nodes n111, n112, n113, n114, n115, and n116. Further, the graph 100 comprises edges e121, e122, e123, e124, e125, e126, and e127. Each of the nodes has one or more adjacent nodes. For example, nodes n112 and n113 are adjacent to node n111, since node n112 shares with node n111 edge e121 and node n113 shares with node n111 edge e122.

When storing a graph in computer memory, the nodes, edges, and attributes may be stored in many different data structures. One way to store a graph is to separate the attribute data from the corresponding nodes. For example, node identifiers may be stored in an array, with each node identifier providing an address or a pointer that points to the location of the attribute data for the corresponding node. The attributes for all nodes may be stored together, and they may be accessed by reading the address or the pointer stored in the corresponding node identifiers. By separating the attribute data from the corresponding nodes, the data structure may be able to provide faster traversing access on the graph.

A graph neural network (GNN) is a type of neural network that may directly operate on a graph. The GNN may be more suitable than traditional neural networks (e.g., a convolutional neural network) for operations on a graph, since the GNN may be better equipped to accommodate the arbitrary size of the graph or the complex topology of the graph. The GNN may perform inference on data described in graph formats. The GNN is capable of performing node-level, edge-level, or graph-level prediction tasks.

GNN processing may involve GNN training and GNN inference, both of which may involve GNN computations. A typical GNN computation on a node (or vertex) may involve aggregating its neighbor's (direct neighbors or each neighbor's neighbors) features (e.g., attribute data) and then computing new activations of the node for determining a feature representation (e.g., feature vector) of the node. Therefore, GNN processing for a small number of nodes often requires input features of a significantly larger number of nodes. Taking all neighbors for message aggregation is too costly since the nodes needed for input features would easily cover a large portion of the graph, especially for real-world graphs that are colossal in size (e.g., with hundreds of millions of nodes with billions of edges).

To make GNN more practical for these real-word applications, node sampling is often adopted to reduce the number of nodes to be involved in the message/feature aggregation. For example, positive sampling and negative sampling may be used to determine the optimization objective and the resulted variance in the GNN processing. For a given root node whose feature representation is being computed, the positive sampling may sample those graph nodes that have connections (direct or indirect) via edges with the root node (e.g., connected to and within a preset distance from the root node); the negative sampling may sample those graph nodes that are not connected via edges with the root graph node (e.g., outside of the preset distance from the root node). The positively sampled nodes and the negatively sampled nodes may be used to train the feature representation of the root node with different objectives.

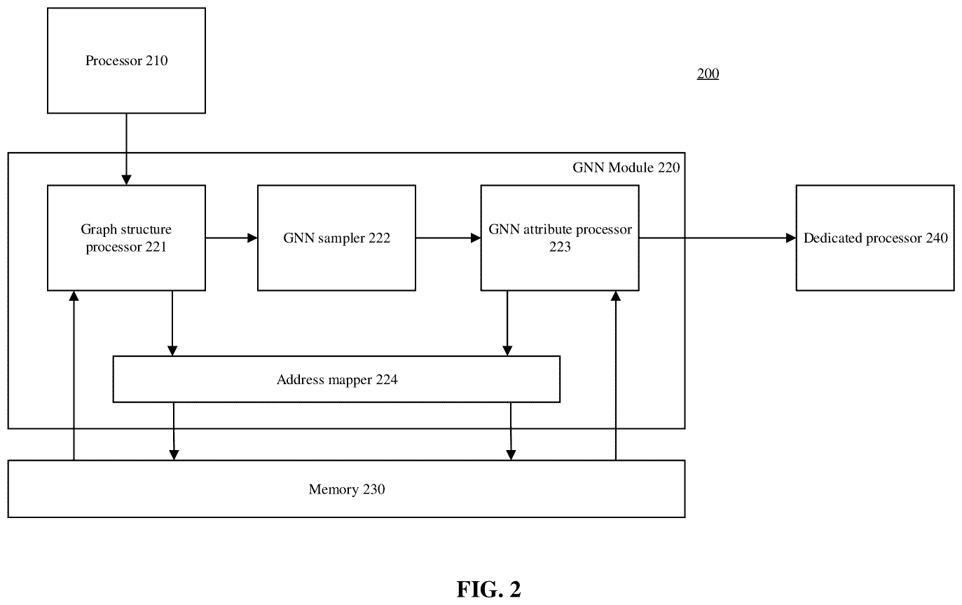

To perform GNN computations, a system may retrieve graph data from a memory, and send the data to one or more processors for processing. FIG. 2 is a schematic of an example system using GNN accelerator architecture, according to some embodiments of this specification. As shown in FIG. 2, a system 200 comprises one or more processors 210, a GNN accelerator 220, a memory 230, and one or more dedicated processors 240. In some embodiments, the one or more processors 210 comprises one or more central processing units (CPU). In some embodiments, the one or more dedicated processors 240 may include one or more CPUs, one or more graphic processing units (GPU), one or more tensor processing units (TPU), one or more neural processing units (NPU), one or more dedicated graph neural network processing units, etc. In some embodiments, the memory 230 may include Synchronous Dynamic Random-Access Memory (SDRAM), such as a Double Data Rate (DDR) SDRAM.

As shown in FIG. 2, the GNN accelerator 220 may receive instructions and information on a GNN from the one or more processors 210, and extract data related to the GNN from the memory 230. After receiving the data from the memory 230, the GNN accelerator 220 may preprocess the data, and send the preprocessed data to the one or more dedicated processors 240 for further processing.

In some embodiments, as shown in FIG. 2, the GNN accelerator 220 may include a graph structure processor 221, a GNN sampler 222, a GNN attribute processor 223, and an address mapper 224. The graph structure processor 221 may be configured to receive instructions and information on the GNN from the one or more processors 210, and fetch information on one or more root nodes and their edges from the memory 230. The graph structure processor 221 may then send the fetched information to the GNN sampler 222.

The GNN sampler 222 may be configured to select, according to the edge information of the one or more root nodes, one or more sampled nodes for GNN processing. In some embodiments, the GNN sampler 222 may select the one or more sampled nodes according to positive sampling or negative sampling. For example, based on the positive sampling, the one or more sampled nodes may be selected from nodes that have a connection via edges with the one or more root nodes (e.g., adjacent to the one or more root nodes). Based on the negative sampling, the one or more sampled nodes may be selected from nodes that are not directly connected via edges with the one or more root nodes (e.g., not adjacent or close to the one or more root nodes). In some embodiments, the positive sampling may select from the neighboring nodes of the root node that are connected to and within a preset distance from the root node. The connection may be a direct (one edge between the source node to the destination node) or indirect (multiple edges from the source node to the destination node) connection. The “preset distance” may be configured according to the implementation. For example, if the preset distance is one, it means only the directly connected neighboring nodes are selected for positive sampling. If the preset distance is infinity, it means that the nodes are not connected, whether directly or indirectly. The negative sampling may select from nodes that are outside the preset distance from the root node. It is appreciated that the sampled nodes may be selected using any algorithms other than the positive sampling and the negative sampling.

Having selected the sampled nodes, the GNN sampler 222 may send the selection information of the sampled nodes to the GNN attribute processor 223. Based on the information of the sampled nodes, the GNN attribute processor 223 may be configured to fetch from the memory 230 information of the sampled nodes. In some embodiments, the information of the sampled nodes may include one or more features or attributes of each of the sampled nodes (also called attribute data). The GNN attribute processor 223 may be further configured to send the fetched information of the sampled nodes and the information of the one or more root nodes and their edges to the dedicated processors 240. The dedicated processors 240 may perform GNN processing based on the information received from the GNN attribute processor 223.

In some embodiments, the graph structure processor 221 and the GNN attribute processor 223 may fetch information from the memory 230 using the address mapper 224. The address mapper may be configured to provide hardware address information in the memory 230 based on information of nodes and edges. For example, a root node as a part of an input GNN may be identified using an identifier n111 (e.g., node n111 of FIG. 1). If the graph structure processor 221 intends to fetch information of the node n111 (e.g., attribute data of the node n111), the graph structure processor 221 may provide the identifier n111 to the address mapper 224, and the address mapper 224 may determine a physical address in the memory 230 where the information for the node n111 (e.g., the attribute data of the node n111) is stored. In some embodiments, the address mapper 224 may also determine one or more physical addresses in the memory 230 where information on the edges of the node n111 is stored (e.g., edges e121 and e122 of FIG. 1).

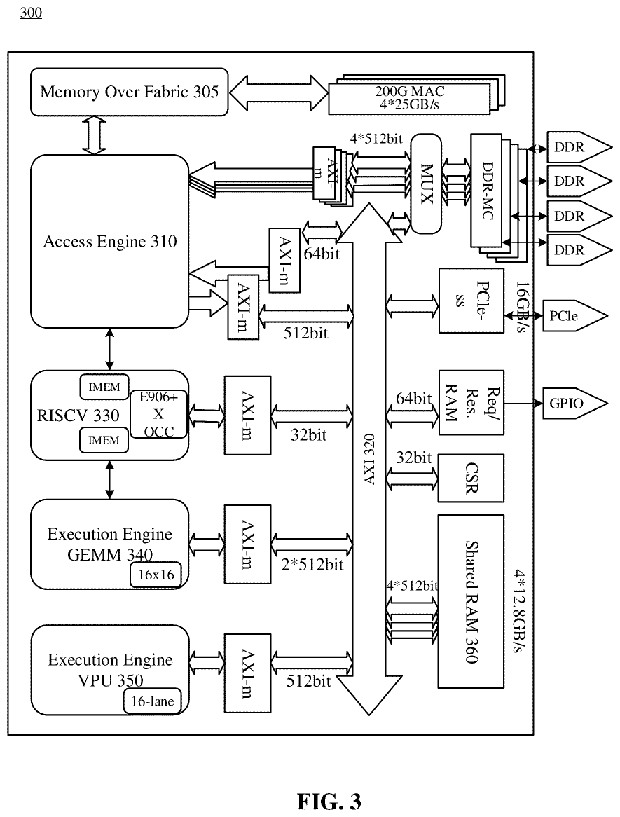

The system 200 shown in FIG. 2 may be used to accelerate GNN memory access for many different systems in accelerating GNN performance. FIG. 3 is a schematic of an example system for accelerating GNN performance, according to some embodiments of this specification. As shown in FIG. 3, an acceleration system 300 comprises a memory over fabric (MoF) 305, an access engine 310, a RISCV 330, a General Matrix Multiply (GEMM) execution engine 340, and a vector processing units (VPU) execution engine 350. The access engine 310 shown in FIG. 3 may be similar to the GNN module 220 shown in FIG. 2. The access engine 310 may be configured to retrieve, from memory (e.g., DDRs as shown in FIG. 2), data needed for performing GNN calculations. For example, the access engine 310 may retrieve node identifiers, edge identifiers, and attribute data corresponding to the node identifiers. The data retrieved by the access engine 310 may be provided to the execution engines (e.g., the GEMM execution engine 340 or the VPU execution engine 350) or processors for GNN-related calculations. As shown in FIG. 3, both types of engines may perform specific GNN-related calculations in an accelerated manner.

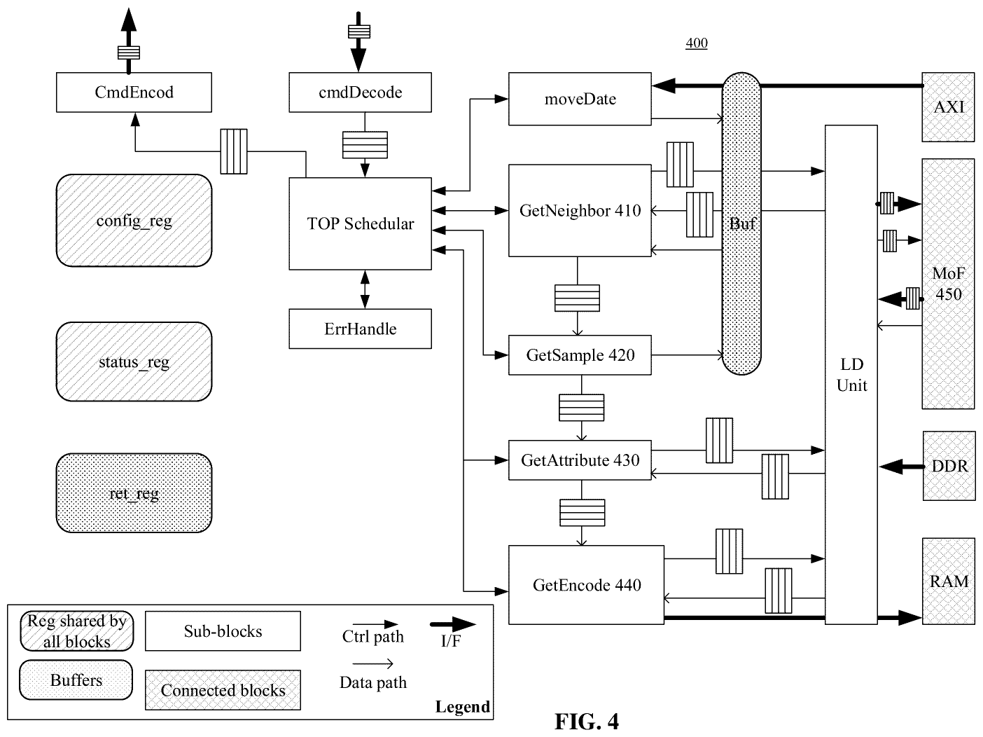

Although the system 300 may include accelerated engines and processors to speed up GNN-related calculations, it is the access engine 310 that may become a bottleneck for the overall performance of the system 300, since the data retrieval performed by the access engine may be slower than the execution engines performing data processing. FIG. 4 is a schematic of an example GNN access engine, according to some embodiments of this specification. It is appreciated that an access engine 400 shown in FIG. 4 may be similar to the access engine 310 shown in FIG. 3. As shown in FIG. 4, the access engine 400 may include a GetNeighbor module 410, a GetSample module 420, a GetAttribute module 430, and a GetEncode module 440.

In some embodiments, the GetNeighbor module 410 is configured to access or identify adjacent nodes for an input node identifier. For example, similar to the graph structure processor 221 shown in FIG. 2, the GetNeighbor module 410 may receive instructions and information on the GNN, and fetch information on one or more nodes, their edges, and their neighbors (adjacent nodes) from DDRs (e.g., corresponding to the memory 230 of FIG. 2). The GetNeighbor module 410 may then send the fetched information to the GetSample module 420 (e.g., corresponding to the GNN Sampler 222 of FIG. 2).

In some embodiments, the GetSample module 420 is configured to receive information on one or more nodes from the GetNeighbor module 410 and perform node sampling on the one or more nodes for GNN processing. For example, similar to the GNN sampler 222 shown in FIG. 2, The GetSample module 420 may be configured to select, according to the edge information of the one or more nodes, one or more sampled nodes for GNN processing. In some embodiments, the GNN sampler 222 may select the one or more sampled nodes according to positive sampling and/or negative sampling. Having selected the sampled nodes, the GetSample module 420 may send the selection information of the sampled nodes to the GetAttribute module 430.

In some embodiments, the GetAttribute module 430 may be configured to receive information of selected or sampled nodes from the GetSample module 420 and fetch attribute information on the sampled nodes from memory (e.g., DDRs shown in FIG. 4 or memory 230 shown in FIG. 2). For example, similar to the GNN attribute processor 223, the GetAttribute module 430 may be configured to fetch from the memory 230 attribute data of the sampled nodes based on the received sampled nodes (e.g., sampled node identifiers). In some embodiments, the GetAttribute module may need to fetch attribute information on the sampled nodes from remote locations. For example, the GetAttribute module may need to fetch the attribute information from other boards. As a result, the GetAttribute module may utilize a memory over fabric (MoF) module 450 to fetch the attribute information from remote locations (e.g., on other boards). In some embodiments, the attribute data of the sampled nodes may include one or more features of each of the sampled nodes.

As shown in FIG. 2, FIG. 3 and FIG. 4, the systems can retrieve graph data (e.g., structure data and attribute data) from the local memory (e.g., DDRs or similar memory types). It is appreciated that the systems can be implemented on a field programmable gate arrays (FPGA). As a result, to enable faster memory access, local DDRs can be implemented on the same FPGA. However, such implementation of local DDRs or similar memories on the FPGA or similar circuitries can be costly. Moreover, DDRs have a limitation in their memory capacity. For graphs that are large in storage size (e.g., larger than 50 gigabytes), DDRs implemented locally may not be able to store a single graph without incurring significant cost. Although the systems may have the option to fetch graph data from a remote location via MoF (e.g., MoF module 450), such memory access incurs longer delays, further adding to the inefficiency of the system. Embodiments of the present disclosure provide hardware systems and methods that provide balanced approaches to store and access graph data from memories.

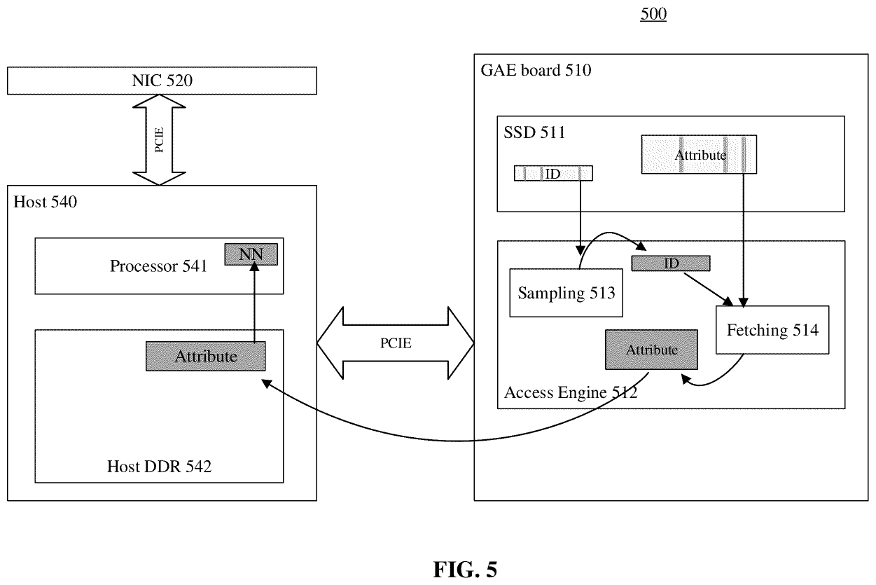

FIG. 5 is a schematic of an example system for accessing GNN data from one or more memories on a circuitry board, according to some embodiments of this specification. As shown in FIG. 5, a system 500 can comprise a host 540 and an graphic access engine (“GAE”) board 510. The host 540 is communicatively coupled with the GAE board 510. In some embodiments, the host 540 is communicatively coupled with the GAE board 510 via a peripheral component interconnect express (“PCIE”) connection. In some embodiments, the host 540 is communicatively coupled (e.g., via PCIE connections) with a network interface controller (“NIC”) 520. The NIC 520 can be configured to connect the host 540 to a computer network (e.g., local network, Internet, etc.), allowing the host 540 to upload to or download data from the computer network.

In some embodiments, the GAE board 510 shown in FIG. 5 may include one or more memories, such as flash drives including solid state drives (SSDs) 511, and an access engine 512. The SSDs 511 and the access engine 512 are communicatively coupled (e.g., via PCIE connections). It is appreciated that the SSDs 511 and the access engine 512 are physically located on the same circuitry board (i.e. the GAE board 510). As a result, latency in data communications between the access engine 512 and the SSDs 511 can be reduced or minimized. The SSDs 511 are configured to store graph data, such as structure data (e.g., node identifiers, neighboring nodes, etc.) or attribute data. In some embodiments, the SSDs 511 are configured to store the structure data and the attribute data of the graph data separately. It is appreciated that the SSDs 511 can include one or more SSDs.

In some embodiments, the access engine 512 shown in FIG. 5 is similar to the access engine 310 shown in FIG. 3 or the access engine 400 shown in FIG. 4, and can include one or more modules or circuitries from the access engine 310 or the access engine 400, such as the GetNeighbor module 410, the GetSample module 420, the GetAttribute module 430, or the GetEncode module 440. For example, the access engine 512 can include a sampling module 513 and a fetching module 514. In some embodiments, the access engine 310 is programmed and implemented on the FPGA.

In some embodiments, the sampling module 513 can be configured perform functions similar to GetNeighbor module 410 and GetSample module 420. For example, the sampling module 513 can fetch structure data (e.g., information on one or more nodes, their edges, and their neighbors) from the SSDs 511, perform node sampling, and identify node identifiers of sampled nodes. The sampling module 513 can be further configured to send the node identifiers of the sampled nodes to the fetching module 514.

In some embodiments, the fetching module 513 can be configured to perform functions similar to GetAttribute module 430. For example, the fetching module 513 can fetch attribute data of the sampled nodes from the SSDs 511 based on the node identifiers of the sampled nodes. In some embodiments, after the fetching module 513 fetches the attribute data of the sampled nodes, the access engine 512 can be configured to send the attribute data of the sampled nodes to the host 540. In some embodiments, the graph data may not fit onto the SSDs 511 in its entirety. As a result, the fetching module 512 can be configured to fetch the attribute data of the sampled nodes from a remote location (e.g., an SSD located off the GAE board 510).

In some embodiments, the host 540 can be configured to receive the attribute data of the sampled nodes from the access engine 512, and perform GNN processing. For example, the host 540 can include a processor 541 and a host DDR 542. The host 540 can be configured to store the attribute data of the sampled nodes in the host DDR 542. The processor 541 can be configured to fetch from the host DDR 542 the attribute data of the sampled nodes, and perform graph neural network processing using the fetched attribute data of the sampled nodes. In some embodiments, the processor is similar to the processor 210 or the dedicated processor 240 shown in FIG. 2. In some embodiments, the host DDR 542 may not have enough memory capacity to store the entire graph data. In fact, in some embodiments, the host DDR 542 may not even have enough memory capacity to store attribute data of all the neighbors. However, since the access engine 512 can perform node sampling on the neighbors and the data transferred from the access engine 512 to the host DDR 542 includes attribute data of the sampled nodes, the host DDR 542 may not have to have enough memory capacity for storing the entire graph, or even the attribute data of all the neighbors. Therefore, the system design on the host 540 can be simplified so that the host 540 does not need to implement an expensive host DDR with a large memory capacity. In some embodiments, the host DDR 542 includes one or more DDRs.

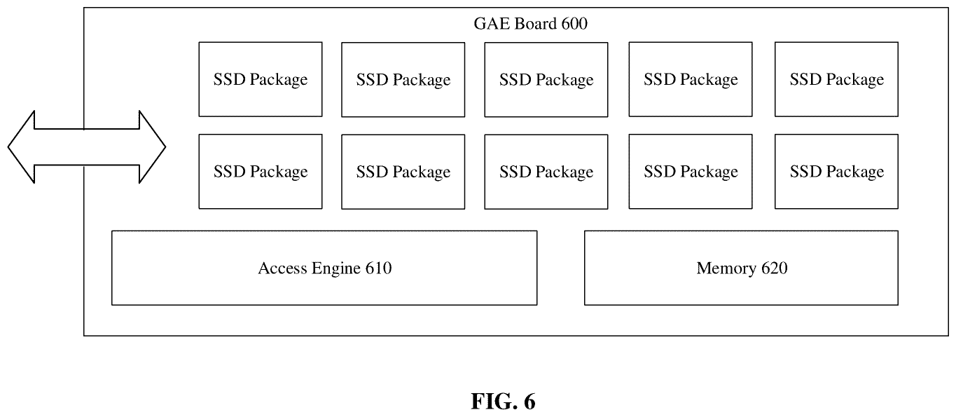

FIG. 6 is a schematic of an example circuitry board for accessing GNN data from a plurality of memories on a circuitry board, according to some embodiments of this specification. As shown in FIG. 6, a GAE board 600 can comprise an access engine 610 and a plurality of memories (e.g., flash drives such as SSDs). For example, as shown in FIG. 6, the GAE board 600 comprises 10 SSDs. In some embodiments, each of the SSDs on the GAE board 600 can be communicatively coupled with the access engine 610, and the plurality of SSDs can be accessed by the access engine 610 in parallel. In some embodiments, one or more of the SSDs is communicatively coupled with the access engine 610 via PCIE or PCIE switches. In some embodiments, the GAE board 600 may be equipped with an M.2 connection, which may be used to connect to the host 540 in FIG. 5. In some embodiments, the GAE board 600 is similar to the GAE board 510, the plurality of SSDs are similar to the SSDs 511, and the access engine 610 is similar to the access engine 512.

In some embodiments, the access engine 610 comprises a memory controller configured to regulate and perform memory accessing of graph data on the plurality of SSDs. In some embodiments, each of the plurality of SSDs has the same storage capacity. For example, each of the plurality of SSDs has a storage capacity of 0.5 terabytes. In some embodiments, the plurality of SSDs can be accessed in parallel. For example, the memory controller of access engine 610 can fetch graph data from some or all of the plurality of SSDs simultaneously. Therefore, many SSDs can be implemented on the GAE board 600, and accessed by the access engine 610 in parallel. As a result, although SSDs can have a longer latency in memory accessing when compared with a DDR, the parallel accessing among the plurality of SSDs can compensate for the latency issue. Moreover, accessing graph data, such as sampled graph data, can involve accessing random memory locations. As a result, implementing many SSDs on the board and spread the graph data on the plurality of SSDs can take advantage of the parallelism among the many SSDs from the system design (e.g., GAE 600 of FIG. 6), providing a more balanced approach to store and access graph data using SSDs instead of the more expensive DDRs in some portion of the hardware design. It is appreciated that the system design shown in FIG. 6 can provide an advantage for data processing for unstructured data types other than the graph data. For example, if accessing an unstructured data type often involves accessing random memory locations, and the memory accessing can be conducted in parallel, the system designs shown in FIG. 6 can still provide a balanced approach between cost and memory accessing efficiency for the unstructured data type.

In some embodiments, the number of the plurality of SSDs to be implemented on the GAE board 600 can be determined based at least on the bandwidth between each of the SSDs and the access engine. For example, if the bandwidth between one SSD and the access engine is 0.5 GB/s and a requirement for the total bandwidth in accessing sampled attribute data is 4 GB/s, the number of SSDs to be implemented on a single GAE board can be 8. In some embodiments, the memory capacity of each SSD can be determined based at least on an estimation of the size of the graph to be stored. For example, if the graphs to be stored are generally under 4 TB in size and there can be as many as 8 SSDs to be implemented on the GAE board 600, a memory capacity of 0.5 TB or higher for each SSD may suffice. In some embodiments, SSDs with a smaller memory capacity are generally less costly to implement. As a result, if a memory capacity of 0.5 TB or higher for each SSD can suffice for the system requirements, the SSDs with a smallest memory capacity that is higher than 0.5 TB (e.g., 512 GB) may be selected for implementation.

In some embodiments, the GAE board 600 comprises a memory 620 configured to facilitate the memory accessing on the plurality of SSDs. In some embodiments, the memory 620 can be a dedicated memory for the GAE board 600. In some embodiments, the memory 620 can be a DRAM (e.g., DDR SDRAM, DDR4 SDRAM, etc.). In some embodiments, the memory 620 is located on the GAE board 600, separately from the access engine 610. For example, if the access engine 610 is implemented on an FPGA, implementing large dedicated memories on the FPGA can be costly. As a result, the memory 620 can be implemented separately from the FPGA to reduce cost. At the same time, the memory 620 is still located on the same board as the access engine 610, hence preserving data transfer efficiency for the system. In some embodiments, the access engine 610 can be implemented on an application-specific integrated circuit (ASIC).

In some embodiments, the access engine 610 is configured to use the memory 620 to facilitate memory accessing of graph data. For example, when the access engine 610 performs sampling or fetching structure data or attribute data from the plurality of SSDs, the access engine 610 can store data in the memory 620 (e.g., as a memory buffer for performing memory accessing). In some embodiments, the memory 620 can be used as a memory buffer for the communication between the GAE board 600 and a host (e.g., the host 540 of FIG. 5). For example, before the GAE board 600 transfers sampled attribute data to the host, the sampled attribute data can be fetched and stored in the memory 620 piece by piece, before the sampled attribute data is ready to be transferred from the memory 620 to the host (e.g., host DDR 542 of FIG. 5).

The GAE board 600 can be configured to be connected with a host (e.g., the host 540). In some embodiments, the connection between the GAE board 600 and the host is based on PCIE or PCIE switches. In some embodiments, the memory controller can be an open-channel controller, and host can be configured to perform memory management through the open-channel controller on the access engine 610 (e.g., via an operating system on the host).

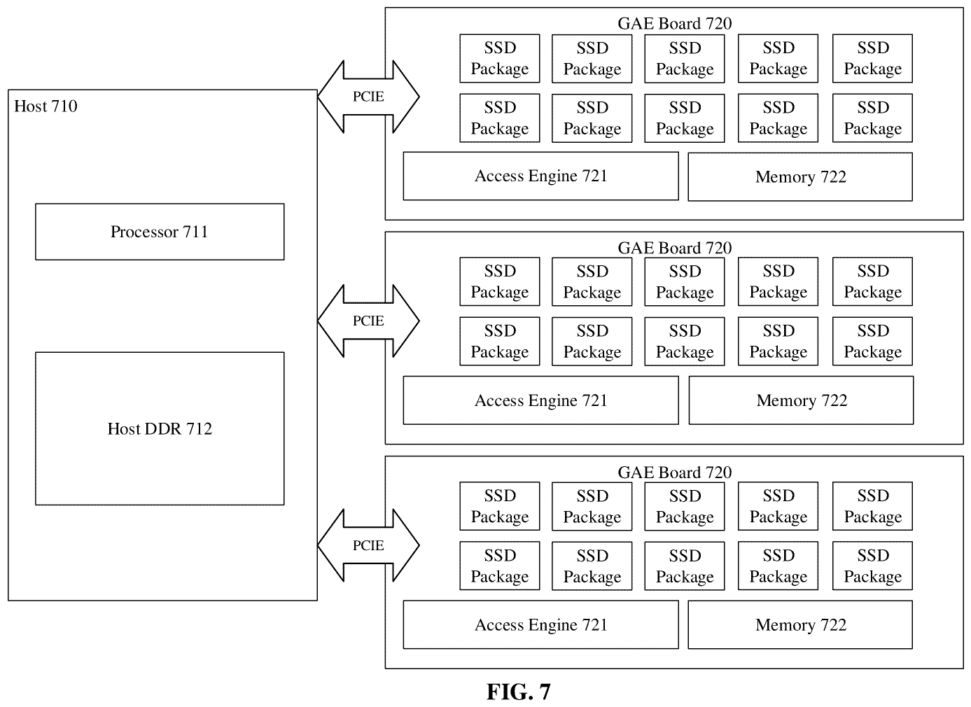

In some embodiments, the host can be communicatively coupled with a plurality of GAE boards. FIG. 7 is a schematic of an example system for accessing GNN data from a plurality of circuitry boards, according to some embodiments of this specification. As shown in FIG. 7, a host 710 is connected with a plurality of GAE boards 720. In some embodiments, the host 710 can communicate with two or more of the GAE boards 720 in parallel. In some embodiments, graph data of one graph can be stored on a number of the GAE boards 720, and the graph data can be accessed by the host 710 in parallel. The system design shown in FIG. 7 allows the functionalities of the GAE boards to be further expanded to accommodate for graphs that require memory capacities beyond a single GAE board. In some embodiments, the host 710 is similar to the host 540 of FIG. 5, and each of the plurality of GAE boards 720 can be similar to the GAE board 600 shown in FIG. 6.

In some embodiments, each of the plurality of GAE boards 720 are similar to each other. For example, each of the plurality of GAE boards 720 can have a same number of SSDs, and each of the SSDs can have a same storage capacity. When the hardware structure across each of the GAE boards is similar, memory access management of the system may be improved since, for example, the host 710 can better predict the available memory capacity of each GAE board and perform data storing or data fetching accordingly. In some embodiments, the host 710 can be configured to perform memory management through an open-channel controller on the access engines 721 across each of the plurality of GAE boards 720 (e.g., via an operating system on the host 710).

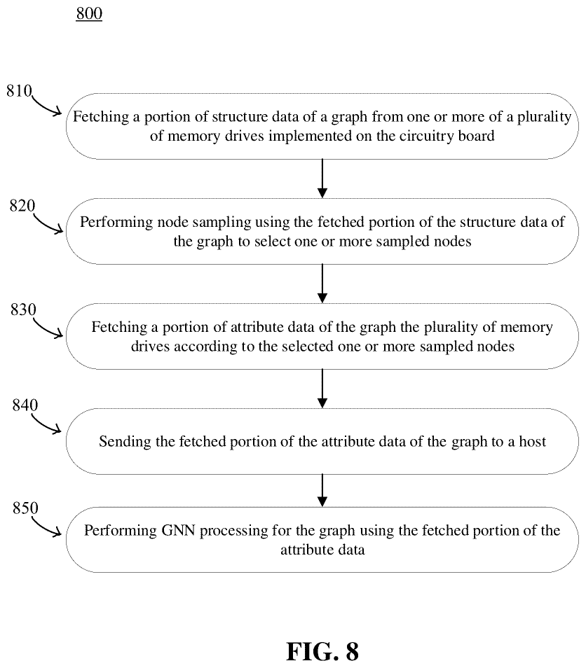

FIG. 8 is an example method for accelerating GNN processing with one or more memories on a circuitry board, according to some embodiments of this specification. The method 800 may be implemented in an environment shown in FIG. 5, FIG. 6, or FIG. 7. The method 800 may be performed by a device, apparatus, or system illustrated by FIGS. 5-7. Depending on the implementation, the method 500 may include additional, fewer, or alternative steps performed in various orders or parallel.

Step 810 includes fetching a portion of structure data of a graph from one or more of a plurality of memory drives implemented on the circuitry board. In some embodiments, the fetching is performed by an access engine circuitry (e.g., access engine 512 of FIG. 5, access engine 610 of FIG. 6, or access engine 721 of FIG. 7). In some embodiments, the access engine circuitry is implemented on a circuitry board (e.g., GAE board 510 of FIG. 5, GAE board 600 of FIG. 6, or GAE board 720 of FIG. 7). In some embodiments, the access engine circuitry is implemented on an FPGA located on the circuitry board. In some embodiments, the plurality of memory drives are SSDs (e.g., SSDs 511 of FIG. 5, SSDs of FIG. 6, or SSDs of FIG. 7). In some embodiments, The plurality of SSDs have the same memory capacity.

Step 820 includes performing node sampling using the fetched portion of the structure data of the graph to select one or more sampled nodes. In some embodiments, the node sampling is performed by the access engine circuitry. In some embodiments, the node sampling is performed in a similar manner as the GetNeighbor module 410 of FIG. 4, GetSample module 420 of FIG. 4, or the sampling module 513 of FIG. 5.

Step 830 includes fetching a portion of attribute data of the graph the plurality of memory drives according to the selected one or more sampled nodes. In some embodiments, the portion of the attribute data of the graph is fetched by the access engine circuitry. In some embodiments, the portion of the attribute data of the graph is fetched from two or more of the plurality of memory drives in parallel. For example, as shown in FIG. 6, each of the SSDs on the GAE board 600 can be communicatively coupled with the access engine 610, and the plurality of SSDs can be accessed by the access engine 610 in parallel. In some embodiments, the circuitry board comprises a dedicated memory communicatively coupled to the access engine circuitry. In some embodiments, the dedicated memory includes one or more DDR SDRAM and is configured to facilitate an implementation of one or more controllers for controlling access to the plurality of memory drives.

Step 840 includes sending the fetched portion of the attribute data of the graph to a host. In some embodiments, the fetched portion of the attribute data of the graph is sent by the access engine circuitry. In some embodiments, the host is similar to the host 540 of FIG. 5 or the host 710 of FIG. 7. In some embodiments, the host is located outside of the circuitry board, and the host is communicatively coupled with the circuitry board via PCIE or PCIE switches.

Step 850 includes performing GNN processing for the graph using the fetched portion of the attribute data. In some embodiments, the GNN processing is performed by the host. In some embodiments, the host comprises one or more processors (e.g., the processor 541 of FIG. 5 or the processor 711 of FIG. 7) configured to perform the GNN processing. In some embodiments, the one or more processors include one or more CPUs, GPUs, NPUs, dedicated graph neural network processing units, etc. In some embodiments, the portion of the attribute data of the graph can be stored in DDR SDRAM (e.g., host DDR 542 of FIG. 5 or host DDR 712 of FIG. 7) of the host, and the DDR SDRAM can facilitate the one or more processors of the host to perform the GNN processing. In some embodiments, the host is communicatively coupled with a plurality of the circuitry boards, and the host is configured to communicate with each of the plurality of the circuitry boards in parallel. The plurality of the circuitry boards can be configured to store the graph data of the graph. In some embodiments, the host can be configured to perform memory management on the plurality of the circuitry boards using open-channel controllers of a plurality of access engine circuitries in the plurality of the circuitry boards.

Each process, method, and algorithm described in the preceding sections may be embodied in, and fully or partially automated by, code modules executed by one or more computer systems or computer processors comprising computer hardware. The processes and algorithms may be implemented partially or wholly in application-specific circuit.

When the functions disclosed herein are implemented in the form of software functional units and sold or used as independent products, they can be stored in a processor executable non-volatile computer-readable storage medium. Particular technical solutions disclosed herein (in whole or in part) or aspects that contribute to current technologies may be embodied in the form of a software product. The software product may be stored in a storage medium, comprising a number of instructions to cause a computing device (which may be a personal computer, a server, a network device, and the like) to execute all or some steps of the methods of the embodiments of the present application. The storage medium may comprise a flash drive, a portable hard drive, ROM, RAM, a magnetic disk, an optical disc, another medium operable to store program code, or any combination thereof.

Particular embodiments further provide a system comprising a processor and a non-transitory computer-readable storage medium storing instructions executable by the processor to cause the system to perform operations corresponding to steps in any method of the embodiments disclosed above. Particular embodiments further provide a non-transitory computer-readable storage medium configured with instructions executable by one or more processors to cause the one or more processors to perform operations corresponding to steps in any method of the embodiments disclosed above.

Embodiments disclosed herein may be implemented through a cloud platform, a server or a server group (hereinafter collectively the “service system”) that interacts with a client. The client may be a terminal device, or a client registered by a user at a platform, where the terminal device may be a mobile terminal, a personal computer (PC), and any device that may be installed with a platform application program.

The various features and processes described above may be used independently of one another or may be combined in various ways. All possible combinations and sub-combinations are intended to fall within the scope of this disclosure. In addition, certain methods or process blocks may be omitted in some implementations. The methods and processes described herein are also not limited to any particular sequence, and the blocks or states relating thereto can be performed in other sequences that are appropriate. For example, described blocks or states may be performed in an order other than that specifically disclosed, or multiple blocks or states may be combined in a single block or state. The example blocks or states may be performed in serial, in parallel, or in some other manner. Blocks or states may be added to or removed from the disclosed example embodiments. The exemplary systems and components described herein may be configured differently than described. For example, elements may be added to, removed from, or rearranged compared to the disclosed example embodiments.

The various operations of example methods described herein may be performed, at least partially, by an algorithm. The algorithm may be comprised in program codes or instructions stored in a memory (e.g., a non-transitory computer-readable storage medium described above). Such algorithm may comprise a machine learning algorithm. In some embodiments, a machine learning algorithm may not explicitly program computers to perform a function but can learn from training data to make a prediction model that performs the function.

The various operations of example methods described herein may be performed, at least partially, by one or more processors that are temporarily configured (e.g., by software) or permanently configured to perform the relevant operations. Whether temporarily or permanently configured, such processors may constitute processor-implemented engines that operate to perform one or more operations or functions described herein.

Similarly, the methods described herein may be at least partially processor-implemented, with a particular processor or processors being an example of hardware. For example, at least some of the operations of a method may be performed by one or more processors or processor-implemented engines. Moreover, the one or more processors may also operate to support performance of the relevant operations in a “cloud computing” environment or as a “software as a service” (SaaS). For example, at least some of the operations may be performed by a group of computers (as examples of machines including processors), with these operations being accessible via a network (e.g., the Internet) and via one or more appropriate interfaces (e.g., an Application Program Interface (API)).

The performance of certain of the operations may be distributed among the processors, not only residing within a single machine, but deployed across a number of machines. In some example embodiments, the processors or processor-implemented engines may be located in a single geographic location (e.g., within a home environment, an office environment, or a server farm). In other example embodiments, the processors or processor-implemented engines may be distributed across a number of geographic locations.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Although an overview of the subject matter has been described with reference to specific example embodiments, various modifications and changes may be made to these embodiments without departing from the broader scope of embodiments of the present disclosure. Such embodiments of the subject matter may be referred to herein, individually or collectively, by the term “invention” merely for convenience and without intending to voluntarily limit the scope of this application to any single disclosure or concept if more than one is, in fact, disclosed.

The embodiments illustrated herein are described in sufficient detail to enable those skilled in the art to practice the teachings disclosed. Other embodiments may be used and derived therefrom, such that structural and logical substitutions and changes may be made without departing from the scope of this disclosure. The Detailed Description, therefore, is not to be taken in a limiting sense, and the scope of various embodiments is defined only by the appended claims, along with the full range of equivalents to which such claims are entitled.

Any process descriptions, elements, or blocks in the flow diagrams described herein and/or depicted in the attached figures should be understood as potentially representing modules, segments, or sections of code which include one or more executable instructions for implementing specific logical functions or steps in the process. Alternate implementations are included within the scope of the embodiments described herein in which elements or functions may be deleted, executed out of order from that shown or discussed, including substantially concurrently or in reverse order, depending on the functionality involved, as would be understood by those skilled in the art.

As used herein, “or” is inclusive and not exclusive, unless expressly indicated otherwise or indicated otherwise by context. Therefore, herein, “A, B, or C” means “A, B, A and B, A and C, B and C, or A, B, and C,” unless expressly indicated otherwise or indicated otherwise by context. Moreover, “and” is both joint and several, unless expressly indicated otherwise or indicated otherwise by context. Therefore, herein, “A and B” means “A and B, jointly or severally,” unless expressly indicated otherwise or indicated otherwise by context. Moreover, plural instances may be provided for resources, operations, or structures described herein as a single instance. Additionally, boundaries between various resources, operations, engines, and data stores are somewhat arbitrary, and particular operations are illustrated in a context of specific illustrative configurations. Other allocations of functionality are envisioned and may fall within a scope of various embodiments of the present disclosure. In general, structures and functionality presented as separate resources in the example configurations may be implemented as a combined structure or resource. Similarly, structures and functionality presented as a single resource may be implemented as separate resources. These and other variations, modifications, additions, and improvements fall within a scope of embodiments of the present disclosure as represented by the appended claims. The specification and drawings are, accordingly, to be regarded in an illustrative rather than a restrictive sense.

The term “include” or “comprise” is used to indicate the existence of the subsequently declared features, but it does not exclude the addition of other features. Conditional language, such as, among others, “can,” “could,” “might,” or “may,” unless specifically stated otherwise, or otherwise understood within the context as used, is generally intended to convey that certain embodiments include, while other embodiments do not include, certain features, elements and/or steps. Thus, such conditional language is not generally intended to imply that features, elements and/or steps are in any way required for one or more embodiments or that one or more embodiments necessarily include logic for deciding, with or without user input or prompting, whether these features, elements and/or steps are included or are to be performed in any particular embodiment.

What is claimed is:

1. A system, comprising:
a host, and
a circuitry board,
wherein the circuitry board comprises:
a plurality of memory drives configured to store structure data of a graph and attribute data of the graph, wherein the plurality of memory drives include flash drives; and
an access engine circuitry communicatively coupled with each of the plurality of memory drives and the host, wherein the access engine circuitry is configured to:
fetch a portion of the structure data of the graph from one or more of the plurality of memory drives;
perform node sampling using the fetched portion of the structure data to select one or more sampled nodes;
fetch a portion of the attribute data of the graph from two or more of the plurality of memory drives in parallel according to the selected one or more sampled nodes; and
send the fetched portion of the attribute data of the graph to the host; and
the host is communicatively coupled with the circuitry board and configured to receive the portion of the attribute data of the graph from the circuitry board, the host comprising:
one or more processors configured to perform graph neural network (GNN) processing for the graph using the portion of the attribute data of the graph.

2. The system of claim 1, wherein the access engine circuitry is implemented on a field programmable gate array (FPGA) located on the circuitry board.

3. The system of claim 1, wherein the plurality of memory drives on the circuitry board are solid state drives (SSDs).

4. The system of claim 3, wherein the plurality of memory drives on the circuitry board have the same memory capacity.

5. The system of claim 1, wherein the access engine circuitry is further configured to access the structure data and the attribute data of the graph from a memory location outside of the circuitry board.

6. The system of claim 1, wherein the one or more processors of the host are central processing units (CPUs), graphics processing units (GPUs), tensor processing units (TPU), neural processing units (NPUs), or graph neural network processing units.

7. The system of claim 1, wherein the host further comprises:
one or more double data rate (DDR) synchronous dynamic random access memory (SDRAM) communicatively coupled with the one or more processors of the host and the circuitry board, the one or more DDR SDRAM configured to:
store the portion of the attribute data of the graph from the circuitry board; and
facilitate the one or more processors of the host to perform GNN processing.

8. The system of claim 1, wherein the circuitry board further comprises a dedicated memory communicatively coupled to the access engine circuitry, wherein the dedicated memory is one or more double data rate (DDR) synchronous dynamic random access memory (SDRAM) and is configured to facilitate an implementation of one or more controllers for controlling access to the plurality of memory drives.

9. The system of claim 1, wherein the host is communicatively coupled with a plurality of the circuitry boards, and the host is configured to communicate with each of the plurality of the circuitry boards in parallel.

10. The system of claim 9, wherein the host is further configured to perform memory management on the plurality of the circuitry boards using open-channel controllers of a plurality of access engine circuitries in the plurality of the circuitry boards.

11. A computer-implemented method, comprising:
fetching, by an access engine circuitry implemented on a circuitry board, a portion of structure data of a graph from one or more of a plurality of memory drives implemented on the circuitry board, wherein the plurality of memory drives include flash drives;
performing, by the access engine circuitry, node sampling using the fetched portion of the structure data of the graph to select one or more sampled nodes;
fetching, by the access engine circuitry, a portion of attribute data of the graph from two or more of the plurality of memory drives in parallel according to the selected one or more sampled nodes;
sending, by the access engine circuitry, the fetched portion of the attribute data of the graph to a host, wherein the host is outside of the circuitry board; and
performing, by one or more processors of the host, graph neural network (GNN) processing for the graph using the fetched portion of the attribute data of the graph.

12. The method of claim 11, wherein the access engine circuitry is implemented on a field programmable gate array (FPGA) located on the circuitry board.

13. The method of claim 11, wherein the plurality of memory drives on the circuitry board are solid state drives (SSDs).

14. The method of claim 13, wherein the plurality of memory drives on the circuitry board have the same memory capacity.

15. The method of claim 11, further comprising:
accessing, by the access engine circuitry, the structure data and the attribute data of the graph from a memory location outside of the circuitry board.

16. The method of claim 11, wherein the one or more processors of the host are central processing units (CPUs), graphics processing units (GPUs), tensor processing units (TPU), neural processing units (NPUs), or graph neural network processing units.

17. The method of claim 11, further comprising:
storing, by one or more double data rate (DDR) synchronous dynamic random access memory (SDRAM) of the host, the portion of the attribute data of the graph from the circuitry board; and
facilitating, by the one or more DDR SDRAM of the host, the one or more processors of the host to perform GNN processing.

18. The method of claim 11, further comprising:
facilitating, by a dedicated memory of the circuitry board, an implementation of one or more controllers for controlling access to the plurality of memory drives, wherein the dedicated memory of the circuitry board is one or more double data rate (DDR) synchronous dynamic random access memory (SDRAM) and is communicatively coupled to the access engine circuitry.

19. The method of claim 11, wherein the host is communicatively coupled with a plurality of the circuitry boards, and the method further comprises:
communicating, by the host, with each of the plurality of the circuitry boards in parallel.

20. A non-transitory computer-readable storage medium storing instructions that, when executed by one or more processors, cause the one or more processors to perform operations comprising:
fetching, by an access engine circuitry implemented on a circuitry board, a portion of structure data of a graph from one or more of a plurality of memory drives implemented on the circuitry board, wherein the plurality of memory drives include flash drives;
performing, by the access engine circuitry, node sampling using the fetched portion of the structure data of the graph to select one or more sampled nodes;
fetching, by the access engine circuitry, a portion of attribute data of the graph from two or more of the plurality of memory drives in parallel according to the selected one or more sampled nodes; and
sending, by the access engine circuitry, the fetched portion of the attribute data of the graph to a host to make the host perform graph neural network (GNN) processing for the graph using the fetched portion of the attribute data of the graph, wherein the host is outside of the circuitry board.
